(19) United States
(12) Patent Application Publication
(10) Pub. No.: US 2006/0028257 A1
(43) Pub. Date: Feb. 9, 2006

(54) System and method for over-temperature protection sensing employing MOSFET on-resistance Rds_on

(76) Inventors: Hong Huang, North Andover, MA (US); Chris M. Young, Austin, TX (US)

Correspondence Address: NIXON PEABODY, LLP, 401 9TH STREET, NW, SUITE 900, WASHINGTON, DC, 20004-2128, US

(21) Appl. No.: 10/910,890

(22) Filed: Aug. 3, 2004

(51) Int. Cl. H03K 3/017

(52) U.S. Cl. 327/175

(57) ABSTRACT

A power supply controller is disclosed that uses power MOSFET on-resistance Rds_on for over-temperature protection. The parameter, on-resistance Rds_on, functions as a temperature dependent variable that enables a pulse width modulation controller to turn OFF when the controller is overheated. The MOSFET on-resistance Rds_on of the pulse width modulation controller senses the temperature that is compared with a predetermined temperature threshold where the pulse width modulation controller detects an over-temperature condition when the sensed temperature exceeds the predetermined temperature threshold. A pulse width modulation controller for over-temperature protection comprises a Rp resistor having a first end and a second end; a voltage comparator circuit, the voltage comparator circuit having a first input, a second input, and an output, the first input of the voltage comparator circuit connected to the second end of the Rp resistor; and a MOSFET having an on-resistance Rds_on when the MOSFET is in an ON state, the Rds_on having a first end and a second end, the second end of the Rds_on connected to the second input of the voltage comparator circuit, the Rds_on sensing a temperature value and the value of the Rds_on fluctuating depending on the change in the temperature value.

### BACKGROUND OF THE INVENTION

1. Field of Invention

The present invention relates generally to power supplies, and more particularly to controllers for over-temperature protection in power supplies.

2. Description of Related Art

Power supplies for portable and desktop electronic devices have received increasing attention and design considerations as new designs call for higher processor power with more functionalities while providing a mechanism to detect for a possible over-heat condition. A type of power supply called the pulse width modulation (PWM) power converter has been widely applied to various electronic products as a technique to improve power conversion efficiency.

The pulse width modulation controller produces a square wave with a variable on-to-off ratio. Modulating a pulse width with the variable on-to-off ratio enables the transferring of a variable amount of power to a load, which effectively reduces the total power consumption and provides an efficient technique for transferring power to the load.

One conventional power converter that typically uses a pulse width modulation controller is a DC-DC converter that has an adjustable step-down circuit with synchronous rectification for powering low dc voltage buses, for example, 3.3V, 5V, and 12V buses. Such DC-DC converters protect against load over-current conditions by using an existing switching device, eliminating the need for a separate current sensing resistor. However, known temperature protection circuits require using a separate component in order to provide such functionality.

Accordingly, there is a need to provide over-temperature protection for a power supply while minimizing the cost of adding more features to a circuit and while keeping the dimensions of the circuit board space relatively compact.

### SUMMARY OF THE INVENTION

The present invention provides a power supply controller that uses power MOSFET on-resistance Rds_on for over-temperature protection. The parameter, on-resistance Rds_on, is used as a temperature dependent variable that causes a pulse width modulation controller to turn OFF when the MOSFET is overheated. The MOSFET on-resistance Rds_on of the pulse width modulation controller senses the temperature that is compared with a predetermined temperature threshold where the pulse width modulation controller detects an over-temperature condition when the sensed temperature exceeds the predetermined temperature threshold.

Broadly stated, the present invention provides a pulse width modulation controller for over-temperature protection comprising a Rp resistor having a first end and a second end; a voltage comparator circuit, the voltage comparator circuit having a first input, a second input, and an output, the first input of the voltage comparator circuit connected to the second end of the Rp resistor; and a MOSFET having an on-resistance Rds_on when the MOSFET is in an ON state, the Rds_on having a first end and a second end, the second end of the Rds_on connected to the second input of the voltage comparator circuit, the Rds_on sensing a temperature value and the value of the Rds_on fluctuating depending on the change in the temperature value; wherein the Rp resistor is a predetermined value relative to a maximum allowable temperature of the Rds_on, the voltage comparator circuit comparing a first voltage drop Vb across the Rds_on with a second voltage drop Vc across the Rp resistor, the voltage comparator circuit generating an over-temperature output signal when the second voltage drop Vc is greater than the first voltage drop Vb when an electrical current Io flowing through the MOSFET Rds_on is equal to, or larger than, the threshold current Ip.

Advantageously, the present invention provides additional functions to a power supply controller while incurring minimal or no extra cost. In addition, the present invention also significantly reduces the amount of board space needed for providing a temperature sensing component.

These and other embodiments, features, aspects, and advantages of the invention will become better understood with regard to the following description, appended claims and accompanying drawings.

### BRIEF DESCRIPTION OF THE DRAWINGS

FIG. 1 is a simplified block diagram illustrating a pulse width modulation controller for over-temperature protection in accordance with the present invention.

FIG. 2A is a circuit diagram illustrating a MOSFET symbol in a circuit in accordance with the present invention; FIG. 2B is a circuit diagram illustrating an equivalent circuit of the MOSFET when the MOSFET is turned ON in accordance with the present invention; FIG. 2C is a circuit diagram illustrating an equivalent circuit of the MOSFET when the MOSFET is turned OFF in accordance with the present invention.

FIG. 3 is a schematic circuit illustrating a first embodiment of a pulse width modulation controller for over-temperature protection using a top side Q1 MOSFET Rds_on with a bottom side Q2 MOSFET in an OFF state in accordance with the present invention.

FIG. 4 is a schematic circuit illustrating the second embodiment of a pulse width modulation controller for over-temperature protection using the bottom side Q2 MOSFET Rds_on with the top side MOSFET in an OFF state in accordance with the present invention.

FIG. 5 is a schematic circuit illustrating a third embodiment of a pulse width modulation controller for over-temperature protection employing a single amplifier in accordance with the present invention.

FIG. 6 is a flow chart illustrating the process as described in the first embodiment to provide over-temperature protection in the power supply by using the top side Q1 MOSFET on_resistance Rds_on as a temperature sensing element in accordance with the present invention.

FIG. 7 is a flow chart illustrating the process as described in the second embodiment to provide over-temperature protection in the power supply by using the bottom side Q2 MOSFET on_resistance Rds_on as a temperature sensing element in accordance with the present invention.

FIG. 8 is a schematic diagram illustrating a non-isolated DC-DC step-down converter in accordance with the present invention.

FIG. 9 is a schematic diagram illustrating a buck converter implemented with an exemplary design of a pulse width modulation controller in accordance with the present invention.

Reference symbols or names are used in the Figures to indicate certain components, aspects or features therein, with reference symbols common to more than one Figure indicating like components, aspects or features shown therein.

### DETAILED DESCRIPTION OF PREFERRED EMBODIMENTS

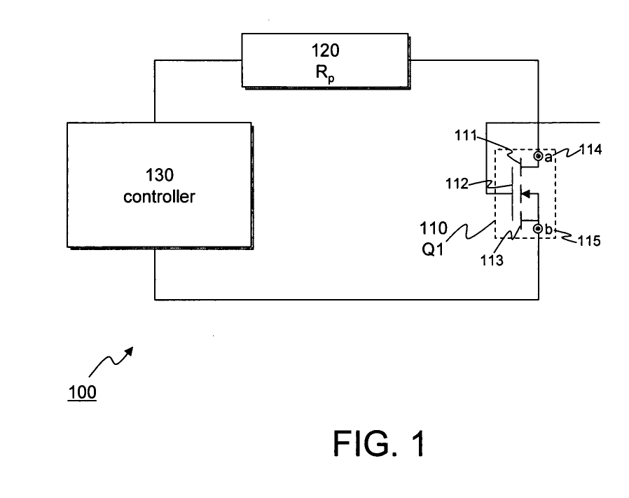

Referring now to FIG. 1, there is shown a simplified block diagram illustrating a pulse width modulation controller 100 for over-temperature protection. The pulse width modulation controller comprises a MOSFET Q1 110, an Rp resistor 120, and a controller 130, where the MOSFET 110 has a drain terminal 111, a gate terminal 112 and a source terminal 113. The voltage drop across the MOSFET 110 between the drain terminal 111 and the source terminal 113 is a function of an on resistance Rds_on, provided that the load current is constant. The value of the on-resistance, Rds_on will vary as a function of temperature. To phrase in another way, the on-resistance Rds_on parameter is a temperature dependent variable. The segment between node-a 114 and node-b 115 illustrates the voltage drop across the drain terminal 111 and the source terminal 113.

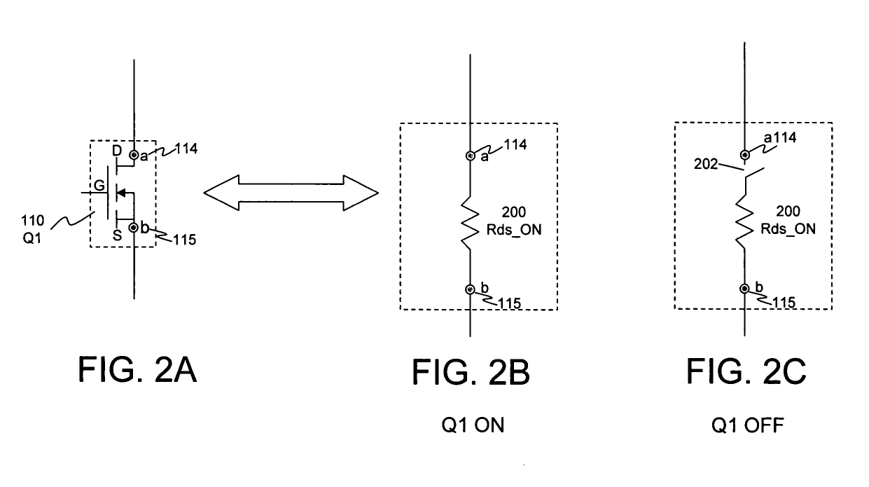

An equivalent circuit of the MOSFET Q1 110 shown in FIG. 1 when the power MOSFET 110 is turned ON (i.e., the switch is closed) is shown in FIG. 2B. As seen in FIG. 2B, 110 can be represented by a resistor, Rds_on 200. That is, the segment between the node-a 114 and the node-b 115 effectively becomes an on-resistance Rds_on 200. The resistance value of Rds_on 200 is typically a small number. The on-resistance Rds_on 200 in the MOSFET Q1 110 can provide both an over-current protection functionality and an over-temperature protection functionality. FIG. 2C shows an equivalent circuit for the MOSFET 110 when the MOSFET 110 is turned OFF (i.e., the switch is open), as represented by the Rds_on 200 with an open switch 202.

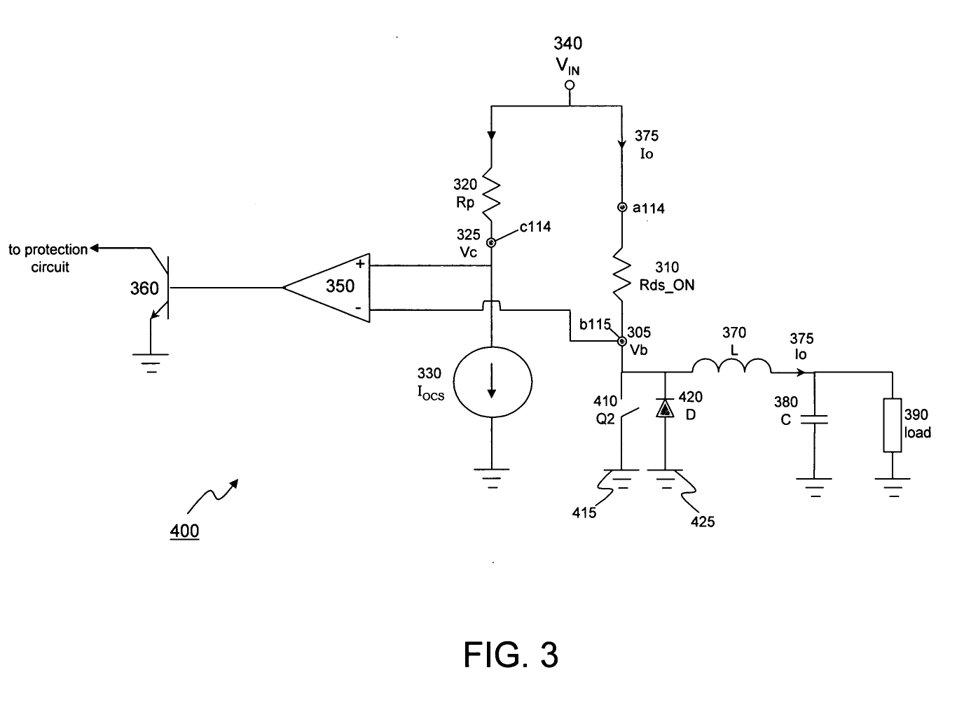

FIG. 3 is a schematic circuit illustrating a first embodiment of a pulse width modulation controller 400 for over-temperature protection by using a top side Q1 MOSFET Rds_on with a bottom side Q2 MOSFET in an OFF state. The controller 400 comprises a top side Q1 MOSFET on-resistance Rds_on 310, a Rp resistor 320, a constant current source 330, a voltage input V_{IN} 340, a voltage comparator 350, a transistor 360, an inductor 370, a capacitor 380, a load 390, a bottom side Q2 MOSFET 410, a ground 415, a diode D 420, and a ground 425. The controller 400 provides an over-temperature protection by using the top side Q1 MOSFET on-resistance Rds_on 310 as a temperature sensing device since the value of the top side Q1 MOSFET on-resistance Rds_on 310 will fluctuate as the temperature changes. The over-temperature protection feature is a function of the interplay between the top side Q1 MOSFET on-resistance Rds_on 310 and the Rp resistor 320, and their respective electrical currents, Io 375 and Ip₁, where Ip₁=I_{OCS} under the assumption that the voltage comparator 350 is an ideal voltage comparator with infinite input impedance of its non-inverting and inverting terminals, and where Ip represents the threshold current for Io. The pulse width modulation controller 400 triggers an over-temperature protection signal when the voltage drop at a node Vc 325 is greater than at a node Vb 305 when the current Io 375 is equal to, or larger than, a predetermined current threshold Ip. The threshold value of Ip is determined from the following parameters: Rp, I_{OCS}, and Rds_on. Among them, the parameter Rds_on varies as a function of temperature. Temperature fluctuation will affect the Ip set point. When the temperature increases, the value of Ip becomes lower. When the temperature decreases, the value of Ip becomes higher. This feature is desired in the power supplies over temperature protection. The voltage Vb 305 at the node-b 115 is a function of the voltage drop across the on_resistance Rds_on 310, i.e., between node-a 114 and node-b 115. This voltage can be represented mathematically as follows: Vb=V_{IN}−I_{O}*Rds_on. The voltage Vc 325 at node-c 116 can be represented mathematically as follows: Vc=V_{IN}−I_{OCS}*Rp. Because the parameter Rds_on 310 is a temperature dependent variable, the change in the value of the Rds_on 310 will in turn affect the value of the voltage drop Vb 305. The voltage drop Vc 325 will also change in value given that the parameter, the Rp resistor 320, is re-calculated in response to the change in the value of the Rds_on 310 as the temperature fluctuates in the controller 400.

A voltage comparator IC 350 compares the voltage drop Vc 325 with the voltage drop Vb 305 to determine if the over-temperature condition is triggered. The over-temperature condition is triggered if Vc>Vb when Io≧Ip. This will result in the following equation: Ip=(Rp*I_{OCS} Rds_on).

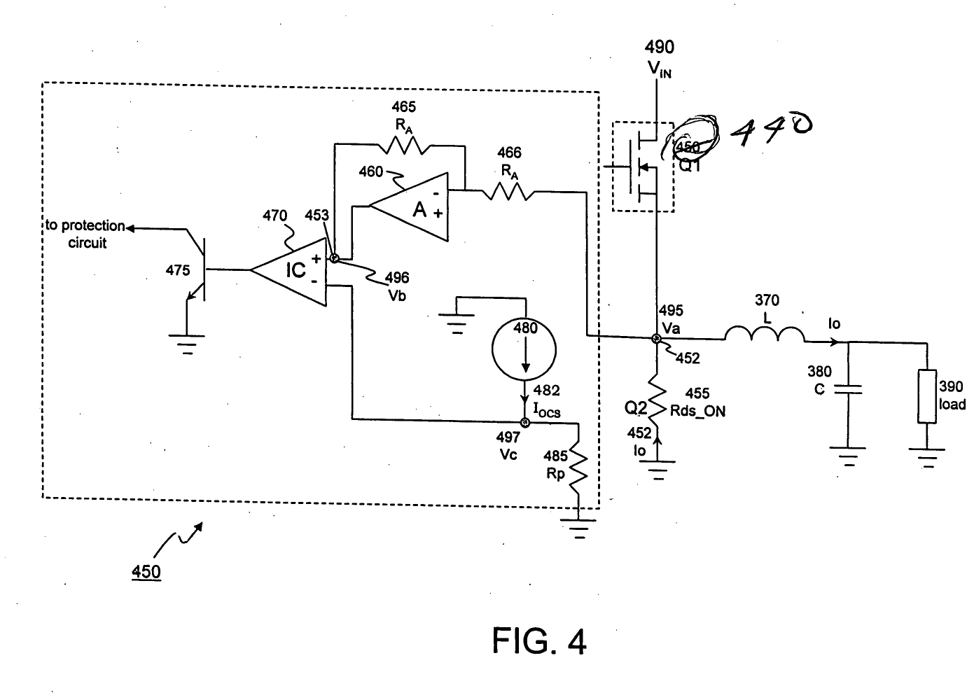

FIG. 4 is a schematic circuit illustrating the second embodiment of a pulse width modulation controller 450 for over-temperature protection using the bottom side MOSFET Rds_on when the bottom side Q2 MOSFET is in an ON state and the top side MOSFET in an OFF state. The controller 450 comprises a top side Q1 MOSFET 450, a bottom side Q2 MOSFET on-resistance Rds_on 455, a Rp resistor 485, a constant current source 480, a voltage input V_{IN} 490, an amplifier A 460, a resistor R_{A} 465, a resistor 466 R_{A}, a voltage comparator 470, a transistor 475, an inductor 370, a capacitor 380, and a load 390. When Q2 MOSFET 455 is in the ON state, Q2 MOSFET 455 is modeled as a resistance of Rds_on 455. When a load current, Io 452, is flowing through Q2 MOSFET Rds_on 455, it produces a negative voltage Va 495 at node 452. Node 452 is connected to a resistor R_{A} 466 and an amplifier A 460 having a feedback resistor R_{A} 465. The voltage Vb 496 at node 453 carries a reverse signal polarity relative to the voltage Va 495, as a function of the one-to-one conversion ratio provided by the amplifier A 460, as shown by the following mathematical equation: Vb=−Va=−(−Io*Rds_on)=Io*Rds_on. In other words, amplifier A 460 is an amplifier with a gain of minus 1. An electrical current, I_{OCS} 482, is generated by a current source 480. Current I_{OCS} 482 causes a voltage drop, Vc 497, across resistor Rp 485, i.e., Vc=I_{OCS}*Rp. An IC 470 is a voltage comparator that compares the voltage Vb 496 and the voltage Vc 497. The over-temperature protection is triggered if Vb>Vc when Io≧Ip, which produces the following equation: Ip=(Rp*I_{OCS})/Rds_on.

While the top side Q1 MOSFET Rds_on 310 provides over-temperature protection for the Q1 MOSFET 310 in FIG. 3, it also provides over-temperature protection for Q2 MOSFET 410. Similarly, the bottom side Q2 MOSFET Rds_on 455 provides over-temperature protection for the Q2 MOSFET 455 in FIG. 4, it also provides over-temperature protection for Q1 MOSFET 450.

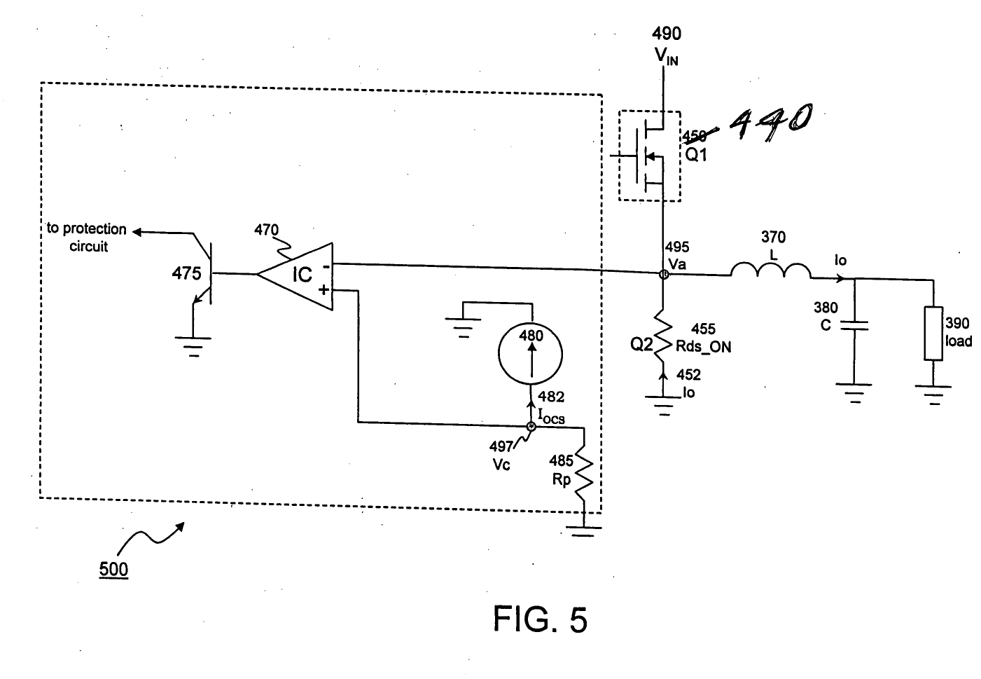

A schematic circuit is shown in FIG. 5 illustrating a third embodiment of a pulse width modulation controller 500 for over-temperature protection wherein only a single amplifier is required. In this embodiment, amplifier A 460 as shown in FIG. 4 is not needed to enable circuit 500 to provide the over-temperature protection capability to the pulse width modulation controller 500 using Q2's Rds_on 455.

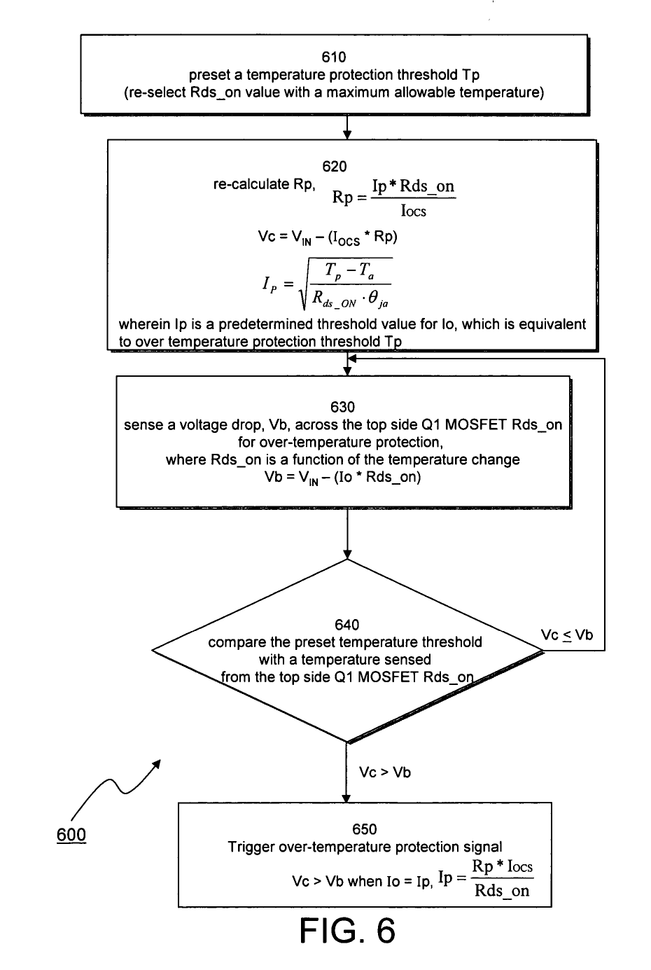

FIG. 6 is a flow chart illustrating the process 600 for providing over-temperature protection in the power supply 300 or 400 by using the top side Q1 MOSFET on_resistance Rds_on 310 as a temperature sensing element. At step 610, the process 600 presets a temperature protection threshold, Tp, for the power supply 300 or 400 by re-selecting the top side Q1 MOSFET Rds_on 310 value with a maximum allowable temperature. Tp is related to the Ip by
T_{P}=I_{P}²·R_{ds}_{_{—}}_{ON}·θⱼₐ+Tₐ
where θⱼₐ is the conversion factor and Tₐ is a reference ambient temperature for the Tp calculation. Then, the corresponding Ip can be obtained as:

$${I}_{P} = \sqrt{\frac{{T}_{p} - {T}_{a}}{{R}_{ds\_ON} \cdot {θ}_{ja}}}$$

In determining the value of the top side Q1 MOSFET Rds_on 310, a derating factor and a corresponding temperature factor are taken into account in adjusting the value of the top side Q1 MOSFET Rds_on 310. After the value of the top side Q1 MOSFET Rds_on 310 is re-selected, the value of Rp 320 is re-calculated to reflect the corresponding change in the Rp 320 relative to the value of the top side Q1 MOSFET Rds_on 310, where Rp=(Ip*Rds_on)/I_{OCS} and Vc=V_{IN}−(I_{OCS}*Rp) such that Ip represents a predetermined threshold value for Io. The voltage drop at the node-c 325 can be represented mathematically as follows: Vc=V_{IN}−(I_{OCS}*Rp). At step 630, the MOSFET Rds_on 310 senses a voltage Vb 305 at node-b 115 for over-temperature protection. The value of the top side Q1 MOSFET Rds_on 310 is a temperature dependent variable that fluctuates relative to the change in the sensed temperature. Optionally, the top side Q1 MOSFET Rds_on 310 also senses a voltage drop Vb 325 across the drain terminal and the source terminal at the node-b 115 for over-current protection. At step 640, the voltage comparator 350 compares the preset temperature threshold with the temperature sensed by the top side Q1 MOSFET Rds_on 310 to determine if an over-temperature condition has been triggered. If the sensed temperature does not exceed the temperature protection threshold, represented as Vc≦Vb, then the process 400 returns to the step 430 for further sensing of temperature to detect whether an over-temperature condition exists. However, if the top side Q1 MOSFET Rds_on 310 senses the temperature that exceeds the over-temperature protection threshold, then the process 600 triggers in step 650 an over-temperature protection signal, represented mathematically as Vc>Vb when Io≧Ip, where Ip=(Rp*I_{OCS}/Rds_on).

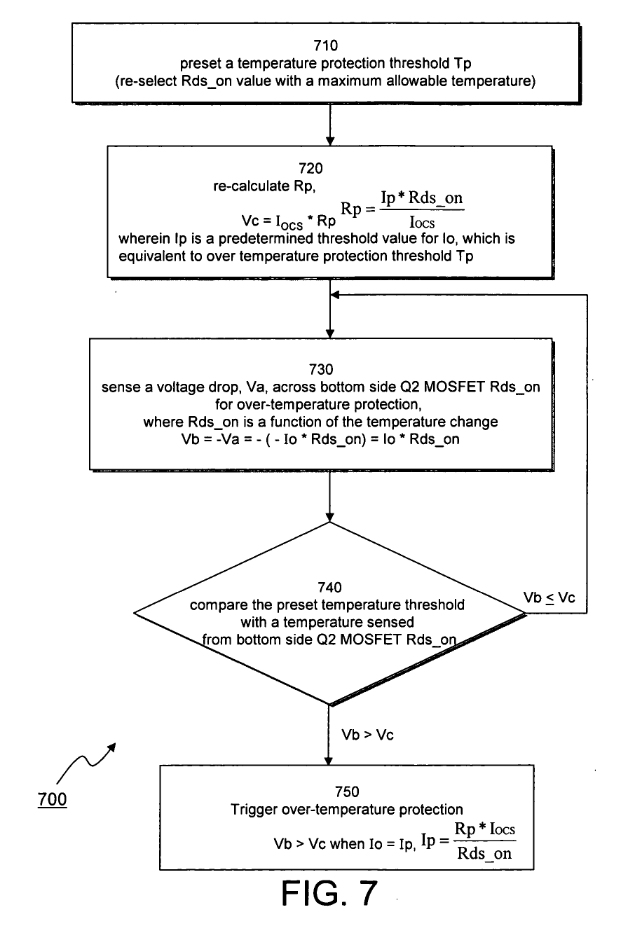

FIG. 7 is a flow chart illustrating the process 700 of providing an over-temperature protection in the power supply 450 by using the bottom side Q2 MOSFET on_resistance Rds_on 455 as a temperature sensing element. At step 710, the process 700 presets a temperature protection threshold for the power supply 450 by re-selecting the bottom side Q2 MOSFET Rds_on 455 value with a maximum allowable temperature. In determining the value of the bottom side Q2 MOSFET Rds_on 455, in which a derating factor and a corresponding temperature factor are taking into account in adjusting the value of the bottom side Q2 MOSFET Rds_on 455. After the value of the bottom side Q2 MOSFET Rds_on 455 is re-selected, the value of Rp 485 is re-calculated to reflect the corresponding change in the Rp 485 relative to the value of the bottom side Q2 MOSFET Rds_on 455, where Rp=(Ip*Rds_on)/I_{OCS} and Vc=V_{IN}−(I_{OCS}*Rp) such that Ip represents a predetermined threshold value for Io. The voltage drop at the node Vb 496 can be represented mathematically as follows: Vb=−Va=−(−Io*Rds_on)=Io*Rds_on. At step 730, the bottom side Q2 MOSFET Rds_on 455 senses a voltage drop across the drain terminal and the source terminal of the Q2 MOSFET Rds_on 455 at the node-a 495 for over-temperature protection. The value of the bottom side Q2 MOSFET Rds_on 455 is a temperature dependent variable that would fluctuate relative to the change in the sensed temperature. Optionally, the bottom side Q2 MOSFET Rds_on 455 also senses a voltage across the drain terminal and the source terminal of the Q2 MOSFET Rds_on 455 at the node Va 495 for over-current protection. At step 740, the voltage comparator 470 compares the preset temperature threshold with the temperature sensed by bottom side Q2 MOSFET Rds_on 455 to determine if an over-temperature condition has been triggered. If the sensed temperature does not exceed the temperature protection threshold, represented as Vb≦Vc, then the process 700 returns to the step 730 for further sensing of temperature to detect if whether an over-temperature condition exists. However, if the bottom side Q2 MOSFET Rds_on 455 senses the temperature that exceeds the over-temperature protection threshold, then the process 700 triggers in step 750 an over-temperature protection to the controller 450, represented mathematically as Vb>Vc when Io=Ip, where Ip=(Rp*I_{OCS}/Rds_on).

One suitable application for the present invention is in non-isolated DC-DC power supplies, which are also referred to as non-isolated point of load (POL) power supplies. Among the non-isolated DC-DC power supplies, pulse width modulation controllers with over-current protection (OCP) are often selected as the implementation choice with an embedded sensing of a voltage drop across a MOSFET Rds_on.

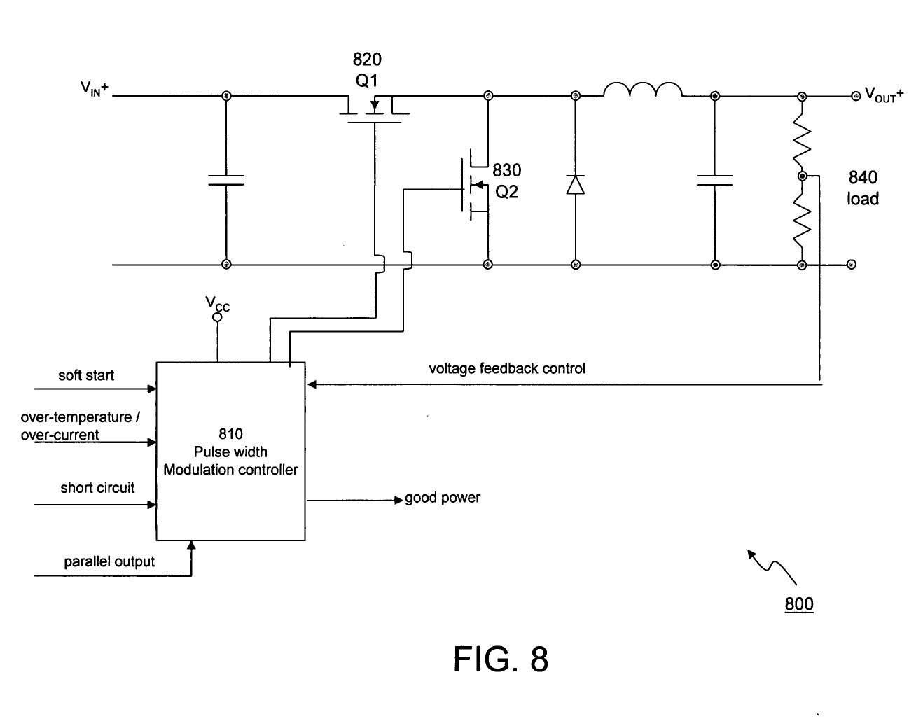

Referring now to FIG. 8, there is shown a schematic diagram illustrating a non-isolated DC-DC step-down converter 800. The non-isolated DC-DC step-down converter 800 comprises a pulse width modulated controller 810, a first MOSFET Q1 820, a second MOSFET Q2 830, and a load 840. The load current flows through power switches Q1 820 and Q2 830 for a portion of time, resulting in a voltage drop across the power switches Q1 820 and Q2 830. If the load current is a constant value, the voltage drop across the power switches Q1 820 and Q2 830 will vary with respect to an on-resistance Rds_on. The amount of the voltage drop will fluctuate relative to the MOSFET temperature. A voltage threshold can be preset to trigger an over-temperature protection signal if the temperature exceeds the voltage threshold.

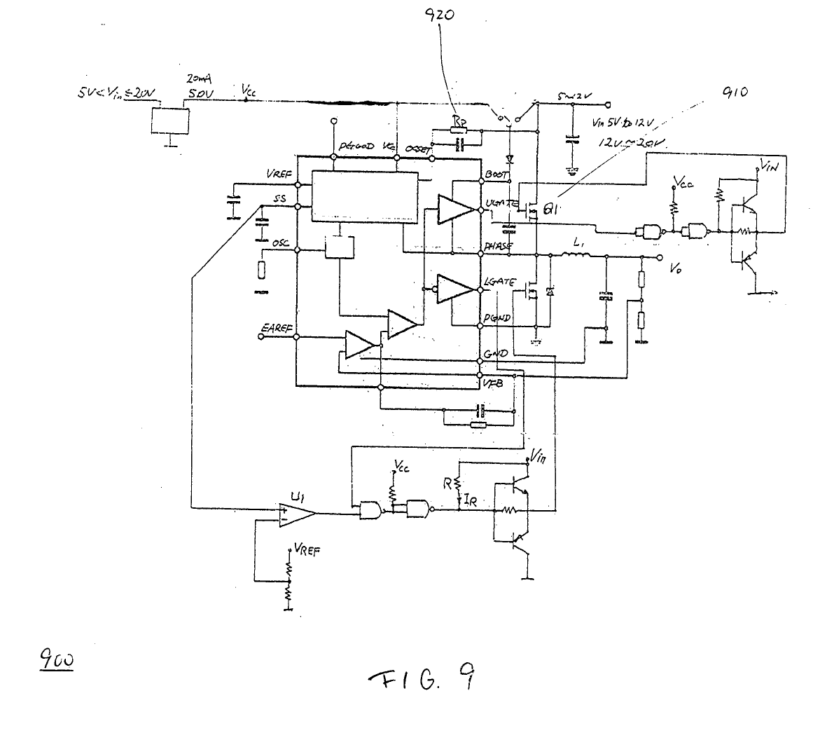

FIG. 9 is a schematic diagram illustrating a pulse width modulation controller 900 in accordance with the present invention. In this embodiment, the pulse width modulation controller 900 provides over-current protection using the MOSFET Rds_on in a Q1 transistor 910 as a current sensing element. A particular pin of the pulse width modulation controller 900 functions as over-current protection by sensing the current flowing through a top side of the MOSFET Q1 910 when the MOSFET Q1 910 is turned ON. The voltage drop across the MOSFET Q1 910, from a drain terminal to a source terminal, is a function of the Rds_on, with the assumption of a constant current flow. To determine the current protection threshold, Ip, it can be represented by the following formula:

$$Ip = \frac{Rp * I ocs}{Rds\_on} \qquad Eq . ( 1 )$$

The Rp resistor 320 is connected to the upper end of the drain terminal of the MOSFET. In one typical specification, the parameter values could be assigned as follows: I_{OCS}=200 μA, Rds_on=11.5 mΩ at 4.5V gate drive voltage, 11 A and 25° C. If Ip=11 A at set-up, then the Rp is calculated to be 632.5 Ωohm from Equation (1).

To apply the present invention for over-temperature protection, the value of Rds_on is re-selected with a maximum allowable temperature. The following example illustrates the calculation of the Rp. If the maximum allowable junction temperature is 175° C. where the derating factor is 85%, the allowable junction temperature is 148° C. A corresponding temperature factor of 1.61 can be found to adjust Rds_on such that Rds_on=11.5 mΩ×1.61 (temperature factor)=18.5 mΩ. Consequently, the value of Rp is re-calculated to produce a value of 1017 Ω.

Another exemplary implementation of the present invention is shown in FIG. 10 illustrating a schematic diagram of a buck power converter 1000 implemented with the pulse width modulation controller 900 as described with respect to FIG. 9. It is apparent to one of ordinary skill in the art that the present invention can be applied to various applications, including but not limited to, an adjustable step down/up controller with synchronous rectification, a single output mobile pulse width modulation controller, a wide-input synchronous buck/boost, such as in a DDR memory power supplies, controller, a multi-phase interleaved synchronous buck converter for VRM (or non VRM) applications, a low-input and high-efficiency synchronous step-down/up controller, and a N-channel MOSFET.

Those skilled in the art can now appreciate from the foregoing description that the broad techniques of the embodiments of the present invention can be implemented in a variety of forms. For example, one of ordinary skill in the art should recognize that a power module can include a power conversion device or a power supply. In addition, the cord reel stand can be designed in various configurations, such as a vanes-shape structure. Therefore, while the embodiments of this invention have been described in connection with particular examples thereof, the true scope of the embodiments of the invention should not be so limited since other modifications, whether explicitly provided for by the specification or implied by the specification, will become apparent to the skilled practitioner upon a study of the drawings, specification, and following claims.

We claim:

1. A pulse width modulation controller for over-temperature protection, comprising:
a first MOSFET having an on-resistance Rds_on when the first MOSFET is in an ON state, the Rds_on having a first end and a second end, the resistive value of the Rds_on fluctuating depending on the change in the temperature value;
an Rp resistor having a first end and a second end, wherein the value of the Rp resistor is computed as a function of a maximum allowable temperature of said MOSFET; and
a voltage comparator circuit, the voltage comparator circuit having a first input, a second input, and an output, the first input of the voltage comparator circuit coupled to said Rp resistor, the voltage comparator circuit comparing a first voltage drop across the Rds_on with a second voltage drop across the Rp resistor, the voltage comparator circuit generating an over-temperature output signal when the second voltage drop is greater than the first voltage drop.

2. The controller of claim 1, further comprising a current source, connected to the second end of the Rp resistor, the current source being a constant current source.

3. The controller of claim 1, further comprising a V_{IN} voltage connected to the first end of the Rp resistor and the first end of the Rds_on.

4. The power supply of claim 1, wherein the on-resistance Rds_on is also used for sensing an over-current condition.

5. The controller of claim 1, further comprising a second MOSFET, connected to the first MOSFET, the first MOSFET providing over-temperature protection for both the first MOSFET and second MOSFET.

6. The controller of claim 1, wherein the Rp resistor is a predetermined value based on the maximum allowable temperature of the Rds_on, a derating factor, and a corresponding temperature factor.

7. A system for over-temperature protection, comprising:
a Rp resistor having a first end and a second end;
a controller having a voltage comparator circuit, the voltage comparator circuit having a first input, a second input, and an output, the first input of the voltage comparator circuit connected to the second end of the Rp resistor; and
a MOSFET having an on-resistance Rds_on when the MOSFET is in an ON state, the Rds_on having a first end and a second end, the second end of the Rds_on connected to the second input of the voltage comparator circuit, the Rds_on sensing a temperature value and the value of the Rds_on fluctuating depending on the change in the temperature value.

8. The system of claim 7, wherein the Rp resistor is a predetermined value relative to a maximum allowable temperature of the Rds_on, the voltage comparator circuit comparing a first voltage drop Vb across the Rds_on with a second voltage drop Vc across the Rp resistor, the voltage comparator circuit generating an over-temperature output signal when the second voltage drop Vc is greater than the first voltage drop Vb when an electrical current Io flowing through the MOSFET Rds_on is equal to, or larger than, the threshold current Ip.

9. The system of claim 7, wherein the controller comprises a pulse width modulation controller.

10. The system of claim 7, further comprising a current source, I_{OCS}, connected to the second end of the Rp resistor, the current source I_{OCS} being a constant current source.

11. The system of claim 7, further comprising a V_{IN} voltage connected between the first end of the Rp resistor and the first end of the Rds_on.

12. The system of claim 7, wherein the on-resistance Rds_on is also used for sensing over-current protection.

13. The system of claim 7, wherein the Rp value is calculated relative to the maximum allowable temperature of the Rds_on, a derating factor, and a corresponding temperature factor.

14. A method for providing an over-temperature protection circuit, comprising:
selecting a predetermined temperature threshold by computing a Rp resistor value from a maximum allowable temperature of an on-resistance Rd_on;
sensing a temperature value from the on-resistance Rds_on of a MOSFET when the MOSFET is in an ON state, the value of the Rds_on fluctuating depending on the sensed temperature; and
comparing the sensed temperature value from the on-resistance Rds_on with a predetermined voltage threshold;
wherein an over-temperature protection is triggered if the value of the sensed temperature is greater than the predetermined temperature threshold.

15. The method of claim 14, wherein the Rp value is calculated relative to the maximum allowable temperature of the Rds_on, a derating factor, and a corresponding temperature factor.

16. The method of claim 14, wherein in the comparing step, comprises triggering an over-temperature if Vc=Vb when Io=Ip, the parameter Vc representing a voltage drop across the Rp resistor, the parameter Vb representing a voltage drop across the Rds_on, the electrical current Io representing an electrical current flowing through the Rds_on, and the electrical current Ip₁ representing an electrical current flowing through the Rp resistor.

17. The method of claim 14, wherein the voltage drop Vc=V_{IN}−I_{OCS}*Rp.

18. The method of claim 14, wherein the voltage drop Vb=V_{IN}−Io*Rds_on.

19. A pulse width modulation controller for over-temperature protection, comprising:
a bottom side MOSFET having an on-resistance Rds_on when the MOSFET is in an ON state, the Rds_on having a first end connected to a first voltage Va and a second end connected to a ground, the resistive value of the Rds_on fluctuating depending on the change in the temperature value;
an Rp resistor having a first end and a second end connected a ground, the value of the Rp resistor being computed as a function of a maximum allowable temperature of said MOSFET; and
a voltage comparator circuit, the voltage comparator circuit having a first input, a second input, and an output, the first input of the voltage comparator circuit connected to the first end of the MOSFET Rds_on for receiving a first voltage drop Va, the second input of the voltage comparator connected to the first end of the Rp resistor for receiving a third voltage drop Vc, a second voltage Vb being of an inverse polarity of Va, the voltage comparator circuit comparing the second voltage drop Vb with the third voltage drop Vc and generating an over-temperature output signal when the second voltage drop Vb is greater than the third voltage drop Vc.

20. The controller of claim 19, further comprising a top side MOSFET having an on-resistance Rds_on that is coupled to the bottom side MOSFET.

21. The controller of claim 20, wherein the bottom side MOSFET Rds_on providing over-temperature protection for both the bottom side MOSFET and the top side MOSFET.

22. The controller of claim 19, further comprising a current source, I_{OCS}, connected to the first end of the Rp resistor, the current source I_{OCS} being a constant current source.

23. The controller of claim 19, further comprising an amplifier A coupled between the first input of the voltage comparator and the first end of the bottom side MOSFET Rds_on, the amplifier A having an input.

24. The controller of claim 23, further comprising one or more resistors connected between the first input of the voltage comparator and the input of the amplifier A.
